(19) United States
(12) Patent Application Publication
(10) Pub. No.: US 2025/0105176 A1
(43) Pub. Date: Mar. 27, 2025

(54) SEMICONDUCTOR DEVICE AND METHOD OF MANUFACTURING SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Teppei TSUKAMOTO, Kamakura (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/601,059

(22) Filed: Mar. 11, 2024

(30) Foreign Application Priority Data
Sep. 21, 2023 (JP) 2023-156365

(51) Int. Cl. H01L 23/00; C25D 5/02; C25D 7/12; H01L 21/768; H01L 23/522; H01L 23/528

(52) U.S. Cl. CPC H01L 24/05; H01L 21/76895; H01L 23/5226; H01L 23/528; H01L 24/03; C25D 5/022; C25D 7/12; H01L 2224/03462; H01L 2224/05012; H01L 2224/0502; H01L 2224/05082; H01L 2224/05147; H01L 2224/05166; H01L 2224/05184; H01L 2224/05556; H01L 2224/05564; H01L 2224/05644; H01L 2224/05655; H01L 2224/05664

(57) ABSTRACT

A semiconductor device according to an embodiment includes a transistor, and a plurality of metal layers that is respectively arranged in a plurality of layers stacked above the transistor, in which the plurality of metal layers includes a first metal layer that is arranged in a lowermost layer of the plurality of layers, a second metal layer that is arranged in an uppermost layer of the plurality of layers and that is thicker than the first metal layer, and a third metal layer that is arranged in the uppermost layer and that is thicker than the second metal layer.

### CROSS-REFERENCE TO RELATED APPLICATIONS

This application is based upon and claims the benefit of priority from Japanese Patent Application No. 2023-156365, filed on Sep. 21, 2023; the entire contents of which are incorporated herein by reference.

### FIELD

Embodiments described herein relate generally to a semiconductor device and a method of manufacturing a semiconductor device.

### BACKGROUND

In manufacturing a semiconductor device, a metal layer being a thick film may be formed using electrolytic plating or the like at the final stage of a back-end-of-line process. The metal layer being a thick film is available as a re-distribution layer to change a wiring drawn position for a lower layer, or as an electrode pad to which a bonding wire or the like is connectable.

### BRIEF DESCRIPTION OF THE DRAWINGS

FIG. 1 is a cross-sectional view illustrating an exemplary configuration of a semiconductor device according to a first embodiment;

FIG. 2 is a cross-sectional view illustrating an exemplary configuration of layers of the semiconductor device according to the first embodiment;

FIGS. 3A to 3G are cross-sectional views illustrating an example of a procedure of a method of manufacturing a semiconductor device according to the first embodiment;

FIGS. 4A to 4E are cross-sectional views illustrating an example of the procedure of the method of manufacturing a semiconductor device according to the first embodiment;

FIGS. 5A to 5F are cross-sectional views illustrating an example of a method of forming wiring layers of a semiconductor device according to a comparative example;

FIGS. 6A and 6B are diagrams each illustrating an exemplary configuration of a semiconductor device according to a second embodiment;

FIGS. 7A to 7E are diagrams illustrating an example of a procedure of a method of manufacturing a semiconductor device according to the second embodiment;

FIGS. 8A to 8F are diagrams illustrating an example of the procedure of the method of manufacturing the semiconductor device according to the second embodiment; and

FIGS. 9A to 9D are diagrams illustrating an example of the procedure of the method of manufacturing the semiconductor device according to the second embodiment.

### DETAILED DESCRIPTION

A semiconductor device according to an embodiment includes a transistor, and a plurality of metal layers that is respectively arranged in a plurality of layers stacked above the transistor, in which the plurality of metal layers includes a first metal layer that is arranged in a lowermost layer of the plurality of layers, a second metal layer that is arranged in an uppermost layer of the plurality of layers and that is thicker than the first metal layer, and a third metal layer that is arranged in the uppermost layer and that is thicker than the second metal layer.

The present invention will be described in detail below with reference to the drawings. Note that the present invention is not limited to the following embodiments. Furthermore, component elements in the following embodiments include component elements that are readily conceivable by a person skilled in the art or that are substantially identical.

### First Embodiment

Hereinafter, a first embodiment will be described in detail with reference to the drawings.

### (Exemplary Configuration of Semiconductor Device)

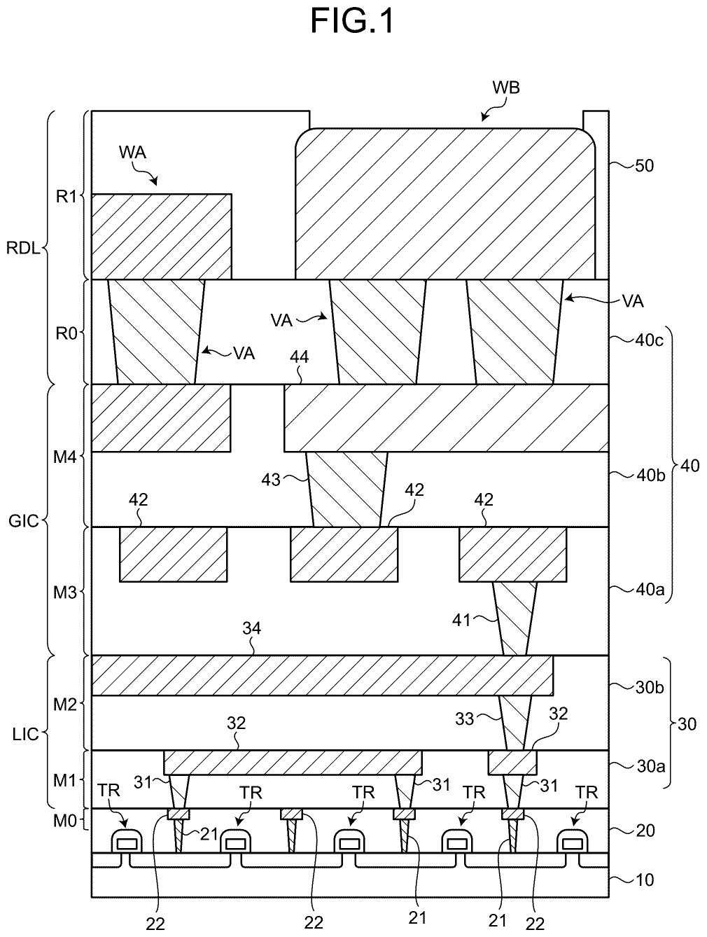

FIG. 1 is a cross-sectional view illustrating an exemplary configuration of a semiconductor device 1 according to the first embodiment. As illustrated in FIG. 1, the semiconductor device 1 of the first embodiment includes a semiconductor substrate 10, a plurality of transistors TR, a plurality of layers M0 to M4, R0, and R1, and the like. However, these layers M0 to M4, R0, and R1 and the like are described by way of example only, and any number of layers may be included in the semiconductor device 1.

The semiconductor substrate 10 is a silicon substrate or the like.

The plurality of transistors TR is provided, for example, on the semiconductor substrate 10. These transistors TR are a field-effect transistor (FET) or the like, and may be configured as, for example, a double-diffused metal-oxide-semiconductor FET (DMOS FET) or the like.

These transistors TR are covered with an insulating layer 20 such as a silicon oxide layer. In the insulating layer 20, contacts 21 and wiring layers 22 that are connected to these transistors TR are arranged. At least part of the insulating layer 20 and at least the wiring layers 22 of the contacts 21 and the wiring layers 22 belong to the layer M0 above the transistors TR. Each of the contacts 21 and the wiring layers 22 is a metal layer that includes, for example, a tungsten layer or the like.

The plurality of layers M0 to M4, R0, and R1 and the like including the layer M0 in the lowermost layer is provided above the transistors TR in this order, and includes the plurality of vias 31, 33, 41, 43, and VA, a plurality of wiring layers 22, 32, 34, 42, 44, WA, and WB, and the like. Design rules in these layers M0 to M4, R0, and R1 are gradually increased from the lower layer side closer to the transistors TR toward the upper layer side. In an example, the contact 21 directly connected to each of the transistors TR, the vias 31, 33, 41, 43, and VA and the like in the upper layers increase toward the upper layers in diameter, length in the extending direction, pitch, and the like, and the wiring layers 22, 32, 34, 42, 44, WA, and WB and the like increase toward the upper layers in width, thickness, pitch, and the like.

The layers M1 and M2 are provided in this order above the layer M0 in the lowermost layer. The layer M1 is provided with the via 31 and the wiring layer 32 that are connected to each wiring layer 22 or the like in the layer M0, and an insulating layer 30a that includes the via 31, the wiring layer 32, and the like. Similarly, the layer M2 is provided with the via 33 and the wiring layer 34 that are connected to the wiring layer 32 or the like in the layer M1, and an insulating layer 30b that includes the via 33 and the wiring layer 34.

The insulating layers 30a and 30b are each, for example, a silicon oxide layer or the like. Hereinafter, these insulating layers 30a and 30b are collectively referred to as insulating layers 30 or the like in some cases. The vias 31 and 33, the wiring layers 32 and 34, and the like are each a metal layer that includes, for example, a Cu layer or the like. Furthermore, the vias 31 and 33, the wiring layers 32 and 34, and the like electrically connect, for example, the plurality of transistors TR to each other, and are also referred to as local inter-connect or the like.

The layers M3 and M4 are provided in this order above the layer M2. The layer M3 is provided with the via 41 and the wiring layer 42 that are connected to the wiring layer 34 or the like in the layer M2, and an insulating layer 40a that includes the via 41 and the wiring layer 42, and the layer M4 is provided with the via 43 and the wiring layer 44 that are connected to the wiring layer 42 or the like in the layer M3, and an insulating layer 40b that includes the via 43 and the wiring layer 44.

The insulating layers 40a and 40b are each, for example, a silicon oxide layer or the like. The vias 41 and 43, the wiring layers 42 and 44, and the like are each a metal layer that includes, for example, a Cu layer or the like. Furthermore, the vias 41 and 43, the wiring layers 42 and 44, and the like electrically connect, for example, circuits including the plurality of transistors TR, and are also referred to as global inter-connect or the like.

The layers R0 and R1 are provided in this order above the layer M4. The layer R0 is provided with the vias VA each connected to the wiring layer 44 or the like in the layer M4, and an insulating layer 40c that includes the vias VA and the like. The layer R1 of the plurality of layers M0 to M4, R0, and R1 and the like is the uppermost layer, and the layer R1 is provided with a wiring layer WA and a wiring layer WB thicker than the wiring layer WA that are connected to the vias VA in the layer R0, and an insulating layer 50 that includes the wiring layers WA and WB and the like. The insulating layer 50 has an opening portion, and an upper surface of the wiring layer WB is exposed from the opening portion.

The insulating layer 40c is, for example, a silicon oxide layer or the like. Hereinafter, the insulating layers 40a to 40c are collectively referred to as insulating layers 40 or the like in some cases. The insulating layer 50 is, for example, a polyimide layer or the like.

The vias VA, the wiring layers WA and WB, and the like are each a metal layer that includes, for example, a Cu layer or the like. Furthermore, the via VA, the wiring layers WA and WB, and the like are also referred to as a re-distribution layer (RDL) formed using, for example, a re-distribution layer forming technology, as described later.

However, in the semiconductor device 1 of the first embodiment, the wiring layer WB of the wiring layers WA and WB functions as an electrode pad connectable to an external device or the like. Meanwhile, the wiring layer WA functions as a so-called re-distribution layer in a narrow sense to change a wiring drawn position for the wiring layer 44 or the like in the layer M4 therebelow.

Note that the configuration of the semiconductor device 1 illustrated in FIG. 1 is described above by way of example only, and the number, combination, and the like of layers included in the semiconductor device 1 are not limited to the example of FIG. 1. For example, the semiconductor device 1 may include an intermediate wiring layer, a semi-global wiring layer, or the like between the local inter-connect and the global inter-connect. In this configuration, the design rules in the intermediate wiring layer and the semi-global wiring layer each have a numerical value between the values of the design rules of the local inter-connect and the global inter-connect, and the intermediate wiring layer and the semi-global wiring layer may have the same design rule.

Furthermore, in the example illustrated in FIG. 1, the vias 31, 33, 41, 43, and VA and the like and the wiring layers 32, 34, 42, 44, WA, and WB and the like corresponding the vias are drawn as separated configurations, but as described later, the vias 31, 33, 41, 43, and VA and the like and the wiring layers 32, 34, 42, 44, WA, and WB and the like corresponding the vias are formed individually or collectively in some cases. In a case where a predetermined via and a wiring layer corresponding the via are collectively formed, the via and the wiring layer can be observed as an integrated configuration.

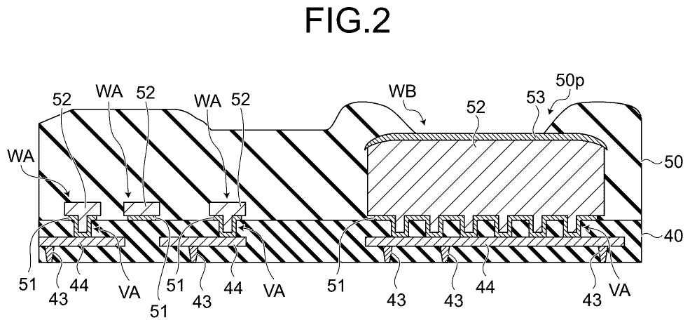

FIG. 2 is a cross-sectional view illustrating an exemplary configuration of the layers R0 and R1 of the semiconductor device 1 according to the first embodiment.

As illustrated in FIG. 2, the insulating layer 40 is provided with a plurality of the vias 43, a plurality of the wiring layers 44, and a plurality of the vias VA, in this order. The insulating layer 40 illustrated in FIG. 2 includes at least part of the insulating layers 40b and 40c of FIG. 1 described above. The plurality of the vias 43 is each connected to any of the plurality of the wiring layers 44, and any of the plurality of the vias VA is connected to each of the plurality of the wiring layers 44.

On the insulating layer 40, the insulating layer 50 is arranged to be configured in the uppermost layer of the semiconductor device 1 and to have an opening portion 50p. Each of the plurality of the vias VA is connected to any of the wiring layers WA and WB included in the insulating layer 50.

More specifically, the wiring layers WA and WB are arranged on the insulating layer 40 belonging to the layers M4 and R0 below the layer R1 to which the wiring layers WA and WB belong. The wiring layer WA as the second metal layer is entirely buried in the insulating layer 50, and the wiring layer WB as the third metal layer has an upper surface, at least part of which is exposed from the opening portion 50p in the insulating layer 50. The insulating layer 50 may have an upper surface having bumps thereon along the unevenness of the wiring layers WA and WB.

Furthermore, the wiring layer WA may be configured to be thicker than at least the wiring layer 22 (see FIG. 1) as the first metal layer in the layer M0 as the lowermost layer, and further, the wiring layer WA may be configured to be thicker than the wiring layer 44 included in the insulating layer 40. The wiring layer WB is thicker than the wiring layer WA, and further has a thickness 40 times or more the thickness of the wiring layer 22 in the layer M0 as the lowermost layer.

For example, even when a process node is reduced to 130 nm, 90 nm, 65 nm, and 40 nm, the wiring layer WA can have a thickness of approximately 5 μm, and the wiring layer WB can have a thickness of 10 μm or more. Note that, for example, when the process node is 130 nm, it means that the transistor IR has a gate length of 130 nm.

As described above, even when the process node is gradually reduced, the thicknesses of the wiring layers WA and WB may be maintained at approximately 5 μm and 10 μm or more, respectively. This is because, since the wiring layers WA and WB are each formed using the re-distribution layer forming technology different from that for the wiring layers 22, 32, 34, 42, and 44 and the like in the layers M0 to M4 therebelow, as described later, approximately 5 μm that is the thickness of the wiring layer WA is closer to a minimum feature size. In addition, this is because, since the wiring layer WB is required to have a predetermined strength, as described later, it is preferable to maintain a thickness of 10 μm or more.

Meanwhile, as the process node is reduced to 130 nm, 90 nm, 65 nm, and 40 nm, the thickness of each wiring layer 22 in the layer M0 as the lowermost layer is gradually reduced, but the wiring layer WB has a thickness of 10 μm or more, that is, the wiring layer WB has a thickness that is, for example, 50 to 77 times the thickness of the wiring layer 22. In this way, the wiring layer WB may have a thickness, for example, 40 times or more, and more preferably, 40 times or more and 80 times or less the thickness of the wiring layer 22.

The wiring layers WA and WB and the vias VA connected to the wiring layers WA and WB each include a plating layer 52 as a first layer and a barrier metal layer 51 as a second layer.

The plating layer 52 is, for example, a Cu layer or the like that is formed by electrolytic plating or the like using a seed layer, which is not illustrated, as an electrode provided on the barrier metal layer 51, and corresponds to a core material of the via VA and a main body portion of the wiring layer WA. The plating layer 52 is continuously provided over the vias VA and the wiring layer WA.

The barrier metal layer 51 is a layer that includes a metal different from the metal of the plating layer 52, such as a Ti layer or a TiW layer, and is provided on lower surfaces of the wiring layers WA and WB, excluding portions to which the vias VA are connected, and a side surface and bottom surface of each via VA. The barrier metal layer 51 is continuously provided from the lower surfaces of the wiring layers WA and WB to the side surface and bottom surface of each via VA. This configuration makes it possible for the barrier metal layer 51 to suppress diffusion of the barrier metal layer 51 and the plating layer 52, which are the Cu layer and the like, in the insulating layer 40 and the like. Note that the barrier metal layer 51 is processed by, for example, wet etching or the like as described later, and therefore, the barrier metal layer 51 may have a side etched shape having a width smaller than that of the portion of the plating layer 52 on the wiring layers WA and WB.

Note that, as described above, the seed layer, which is not illustrated, is arranged between the barrier metal layer 51 and the plating layer 52. In other words, the seed layer is provided on the lower surfaces of the wiring layers WA and WB, excluding portions to which the vias VA are connected, the side surface and bottom surface of each via VA, and on the inner side of the barrier metal layer 51. The seed layer is, for example, a Cu layer or the like similarly to the plating layer 52, and serves as an electrode when the plating layer 52, which is the Cu layer or the like, is formed by the electrolytic plating.

In addition, the wiring layer WB further includes a coating layer 53 as a third layer, on a surface of the plating layer 52 exposed from the opening portion 50p of the insulating layer 50. The coating layer 53 includes a metal different from the metal of the plating layer 52, and is, for example, a NiPd layer, NiAu layer, NiPdAu layer, Au layer, or the like. The coating layer 53 has an outer edge portion that is covered and protected by the insulating layer 50.

The upper surface of the wiring layer WB including the coating layer 53 may not have a flat shape but may have a round shape with an outer edge portion rounded. The outer edge portion of the coating layer 53 may protrude from an outer edge portion of the plating layer 52. Even when the coating layer 53 has such a shape, the wiring layer WB having the round shape alleviates concentration of stress of the insulating layer 50 protecting the outer edge portion of the wiring layer WB, at an end portion of the wiring layer WB, suppressing removal of the insulating layer 50.

The wiring layer WB functions as, for example, the electrode pad of the semiconductor device 1 connected to the external device. Providing the coating layer 53 on the upper surface of the wiring layer WB, as described above, makes it possible, for example, to connect a bonding wire to the wiring layer WB, using the coating layer 53 as a bonding layer.

Meanwhile, as described above, the wiring layer WA functions as the re-distribution layer to change the wiring drawn position for the wiring layer 44 and the like therebelow. The wiring layer WA is configured to be thinner than the wiring layer WB, and therefore, the design rule finer than that of the wiring layer WB is applicable. In other words, in addition to the thickness of the wiring layer WA, the width, pitch, and the like of the wiring layer WA may be configured finer than those of the wiring layer WB.

When the plating layer 52 on the wiring layers WA and WB have the Cu layers, Cu is an example of a first metal. Furthermore, when the coating layer 53 of the wiring layer WB is a NiPd layer, NiAu layer, NiPdAu layer, Au layer, or the like, these metals used for the coating layer 53 are an example of a second metal.

### (Method of Manufacturing Semiconductor Device)

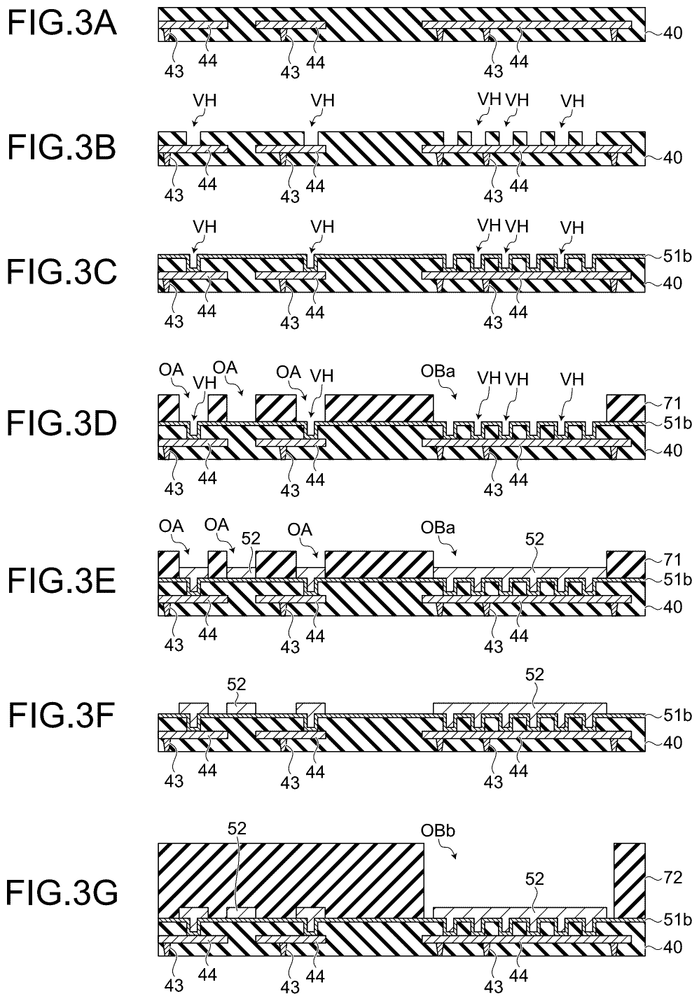

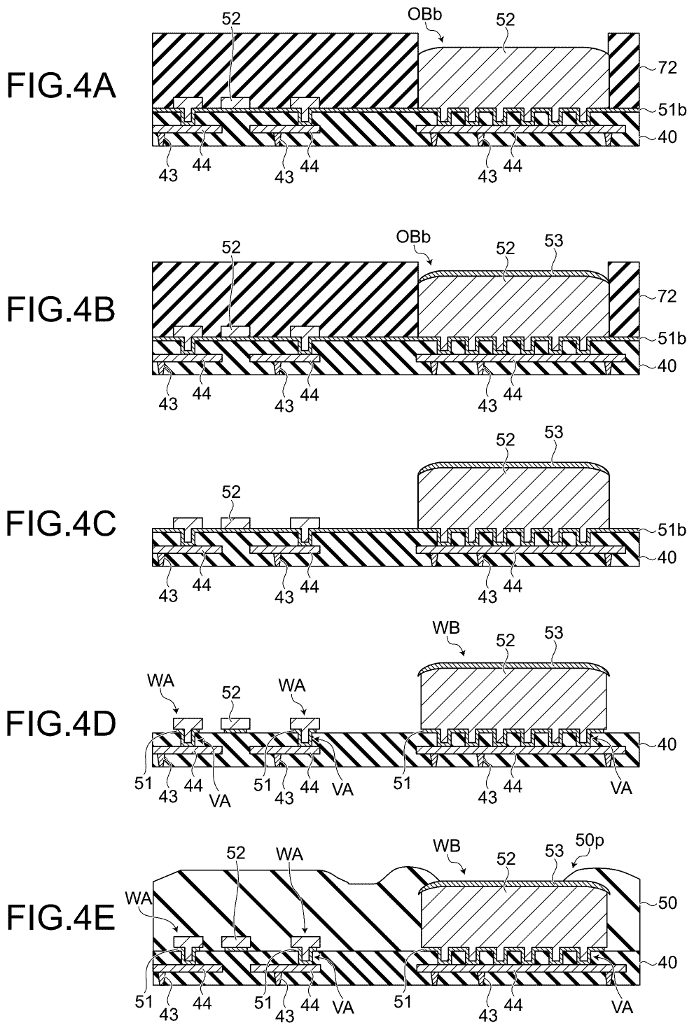

Next, a method of manufacturing the semiconductor device 1 according to the first embodiment will be described with reference to FIGS. 3A to 4E. FIGS. 3A to 4E are cross-sectional views illustrating an example of a procedure of the method of manufacturing the semiconductor device 1 according to the first embodiment.

Note that FIGS. 3A to 4E mainly illustrate a method of forming various configurations in the layers R0 and R1 of the semiconductor device 1. Various configurations, the transistors TR, and the like in the layers M0 to M4 below the layers R0 and R1 can be formed by a general semiconductor process.

In other words, referring to FIG. 1, a gate insulating layer, a gate electrode, and the like are formed on the semiconductor substrate 10, and predetermined conductive impurities are diffused into the semiconductor substrate 10 to form source/drain regions, and the transistors TR are formed. In addition, the insulating layer 20 is formed to cover the transistors TR.

The process having been described above is also referred to as, for example, a front-end-of-line (FEOL) process or the like. On the other hand, a subsequent process is also referred to as a back-end-of-line (BEOL) process or the like.

In the back-end-of-line process, when various configurations are formed in the layers M0 to M4, precision processing such as plasma etching or chemical vapor deposition (CVD) is exclusively used. In other words, contact holes and wiring trenches are formed in the insulating layer 20 in the layer M0, and the contacts 21 and the wiring layers 22 are formed in the contact holes and the wiring trenches. In addition, while forming the insulating layers 30a, 30b, 40a, and 40b and the like in the upper layers M1 to M4, via holes, wiring trenches, and the like are sequentially formed therein, and the vias 31, 33, 41, and 43, the wiring layers 32, 34, 42, and 44, and the like are formed in the via holes and the wiring trenches, respectively.

Note that, more specifically, as a method of forming the various configurations, there is a single damascene process to individually form the vias 31, 33, 41, and 43 and the like and corresponding wiring layers 32, 34, 42, and 44 and the like when the Cu layer is adopted as the metal layer, or a dual damascene process to collectively form these vias 31, 33, 41, and 43, the wiring layers 32, 34, 42, and 44, and the like.

For example, in an example of a combination of the via 31 and the wiring layer 32, in the single damascene process, a via hole is formed, the metal layer is filled in the via hole to form the via 31, before a wiring trench is formed on the formed via 31, and then, the metal layer is filled in the wiring trench to form the wiring layer 32.

On the other hand, in the dual damascene process, after the via hole and the wiring trench are formed, the via hole and the wiring trench are collectively filled with the metal layer to simultaneously form the via 31 and the wiring layer 32.

Furthermore, when the via hole and the wiring trench are formed by the dual damascene process, either a process (via first process) or a process (trench first process) is mainly adopted. In the process (via first process), after the via hole is formed, the wiring trench is formed by expanding an upper end portion of the via hole, and in the process (trench first process), after the wiring trench is formed, the via hole extending in a depth direction from a bottom surface of the wiring trench is formed.

In the semiconductor device 1 of the first embodiment, the vias 31, 33, 41, and 43, the wiring layers 32, 34, 42, and 44, and the like can be formed by, for example, any of the methods described above, different formation methods may be used in different layers, and in addition, an Al layer, an Al—Si—Cu layer, and the like may be used as a wiring material.

A process of forming the via VA, the wiring layers WA and WB, and the like in the layers R0 and R1 is performed as follows in the final stage of the back-end-of-line process, by using an inexpensive processing with reduced manufacturing load, such as lift-off using photolithography or the like or electrolytic plating.

As illustrated in FIG. 3A, the vias 43 and the wiring layers 44 are formed in the insulating layer 40.

As illustrated in FIG. 3B, the insulating layer 40 is processed to form a plurality of via holes VH reaching the wiring layers 44.

As illustrated in FIG. 3C, a barrier metal layer 51b and the seed layer are formed in this order on a surface of the insulating layer 40 and a side surface and bottom surface of each of the via holes VH. The barrier metal layer 51b is formed in the via hole VH or the like by sputtering a target such as Ti or TiW. The seed layer is formed on the barrier metal layer 51b by sputtering a target such as Cu.

Note that when the barrier metal layer 51b and the seed layer are formed by sputtering or the like, it is preferable to continuously form the barrier metal layer 51b and the seed layer while holding the semiconductor substrate 10 to be treated under vacuum. Furthermore, for the barrier metal layer 51b, it is preferable to use a material having a barrier property against Cu or the like in the seed layer and plating layer 52 which are to be formed later and having high adhesion to the insulating layer 50. The Ti, TiW, or the like described above satisfies these conditions.

As illustrated in FIG. 3D, a mask pattern 71 as a first mask pattern such as a photoresist layer is formed to cover the insulating layer 40, the barrier metal layer 51b on the insulating layer 40, and the like. The mask pattern 71 has a plurality of opening portions OA and OBa as second and first opening portions, at positions where the via holes VH are formed.

As illustrated in FIG. 3E, the plating layer 52 being the Cu layer or the like are each formed by electrolytic plating or the like, using as an electrode, the seed layer formed on the barrier metal layer 51b exposed from the opening portions OA and OBa of the mask pattern 71. The plating layer 52 as the first layer is formed to be thicker than at least the wiring layer 32 in the layer M0 as the lowermost layer and further thicker than the wiring layer 44 formed in the insulating layer 40 below the layer R0.

Note that the plating layer 52 and the like formed in each of the opening portions OA of the opening portions OA and OBa becomes the wiring layer WA that functions as the re-distribution layer. Therefore, the opening portions OA of the mask pattern 71 described above are formed at positions to which the wiring drawn position for the wiring layer 44 can be changed so that the wiring layer WA can rewire the lower wiring layer 44.

As illustrated in FIG. 3F, the mask pattern 71 is removed by ashing or the like using oxygen plasma.

Note that as described above, the process of forming a wiring pattern or the like by using the mask pattern 71 or the like as a template is also referred to as lift-off or the like.

As illustrated in FIG. 3G, a mask pattern 72 as a second mask pattern such as a photoresist layer is formed to cover the insulating layer 40, the barrier metal layer 51b on the insulating layer 40, and part of the plating layer 52. The mask pattern 72 has an opening portion OBb as a third opening portion at a position overlapping with the opening portion OBa of the mask pattern 71 described above.

Thus, the plating layer 52 and the like having formed in the opening portion OA of the mask pattern 71 are covered with the mask pattern 72. In addition, the plating layer 52 is exposed from the opening portion OBb. At this time, from the viewpoint of alignment accuracy of the mask pattern 72 with the plating layer 52, the opening portion OBb of the mask pattern 72 is preferably formed larger than the opening portion OBa of the mask pattern 71.

As illustrated in FIG. 4A, the Cu layer or the like is formed to be further thicker by electrolytic plating or the like, by using the plating layer 52 exposed from the opening portion OBb of the mask pattern 72, as an electrode. In the opening portion OBb, the plating layer 52 formed into a thick film has a thickness 40 times or more the thickness of the wiring layer 22 in the layer M0 as the lowermost layer. Furthermore, the opening portion OBb of the mask pattern 72 is formed to be larger than the opening portion OBa of the mask pattern 71, and electrolytic plating is further performed on the basis of the plating layer 52 having formed to have a size smaller than that of the opening portion OBb. Therefore, an upper end of the plating layer 52 formed into the thick film is allowed to have a round shape.

As illustrated in FIG. 4B, the coating layer 53 as the second layer, such as a NiPd layer, NiAu layer, NiPdAu layer, or Au layer, is formed on the plating layer 52 formed into the thick film, which is formed in the opening portion OBb of the mask pattern 72 by, for example, electroless plating or the like.

As illustrated in FIG. 4C, the mask pattern 72 is removed by ashing or the like using oxygen plasma.

As illustrated in FIG. 4D, the seed layer, which is not illustrated, and the barrier metal layer 51b are removed from the surface of the insulating layer 40 located at portions not covered with the plating layer 52 or the like, by wet etching or the like. Therefore, the seed layer and barrier metal layer 51 that have the patterns of the wiring layers WA and WB are formed, and the wiring layer WA and the wiring layer WB are formed. The wiring layer WA is a thin layer without the coating layer 53, and the wiring layer WB is configured into a thick film with the coating layer 53.

Note that in wet etching of the barrier metal layer 51 and the like, side etching occurs in the seed layer and the barrier metal layer 51, and further, the plating layer 52 on the barrier metal layer 51 are partially etched. Therefore, the width of the plating layer 52 may be reduced, and the coating layer 53 on the plating layer 52 may have a shape protruding from an end of the plating layer 52 into an eaves shape.

As illustrated in FIG. 4E, the opening portion 50p is provided at a position where the wiring layer WB is formed, and the insulating layer 50 such as the polyimide layer covering the insulating layer 40 including the wiring layer WA is formed. In this configuration, bumps may be generated on the upper surface of the insulating layer 50 to follow the shape of the wiring layers WA and WB.

As described above, the semiconductor device 1 according to the first embodiment is manufactured.

### (Comparative Example)

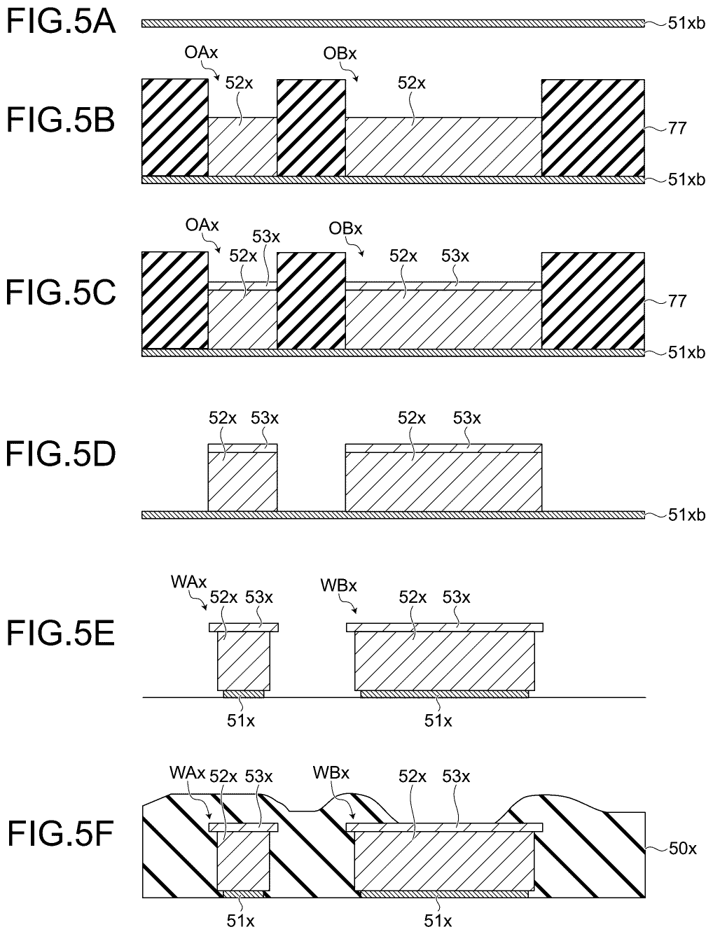

Next, an example of forming wiring layers WAx and WBx according to a comparative example will be described with reference to FIGS. 5A to 5F.

FIGS. 5A to 5F are cross-sectional views illustrating an example of a method of forming wiring layers WAx and WBx of a semiconductor device according to the comparative example. As illustrated in FIGS. 5A to 5F, in a process of forming the re-distribution layer by lift-off using photolithography or the like, electrolytic plating, and the like, it is difficult to make the thicknesses of the wiring layers WAx and WBx different, and these wiring layers WAx and WBx are formed to have a single thickness.

In other words, a barrier metal layer 51xb and the like are formed as illustrated in FIG. 5A, a mask pattern 77 covering the barrier metal layer 51xb is formed as illustrated in FIG. 5B, a plating layer 52x is formed in opening portions OAx and OBx of the mask pattern 77, and a coating layer 53x is further formed as illustrated in FIG. 5C. In addition, after the mask pattern 77 is removed as illustrated in FIG. 5D, the barrier metal layer 51xb and the like at an exposed portion are removed as illustrated in FIG. 5E to form the wiring layers WAx and WBx having the same thickness. Thereafter, as illustrated in FIG. 5F, an insulating layer 50x is formed so that the wiring layer WAx is covered and upper surface of the wiring layer WBx is exposed.

Therefore, the wiring layer WAx functioning as the re-distribution layer and the wiring layer WBx functioning as the electrode pad are formed.

As described above, in the semiconductor device of the comparative example, the wiring layer WAx functioning as the re-distribution layer is formed identically to, for example, the thickness of the wiring layer WBx functioning as the electrode pad. Accordingly, a design rule increased for a thick film process is also applied to the wiring layer WAx, making it difficult to miniaturize the wiring layer WAx. This can be a factor that hinders the reduction in size of the semiconductor device.

Furthermore, the coating layer 53x serving as the bonding layer with the bonding wire is also formed in the wiring layer WAx that does not require the bonding layer, causing an increase in process cost. In addition, the wiring patterns of a thick film has a risk of removal of the insulating layer 50x serving as the protective layer for the wiring patterns, and therefore, it is necessary to perform appearance inspection to secure bonding reliability and improving a yield in bonding. Both the wiring layers WAx and WBx formed into the thick film increases the total number of inspections for the wiring layers WAx and WBx as well, and further, the process cost increases.

Therefore, it is considered to separately form the wiring layer WAx as the re-distribution layer, in a layer below the wiring layer WBx as the electrode pad. However, an increased number of layers of the semiconductor device eventually causes an increase in manufacturing load and process cost.

According to the first embodiment, the semiconductor device 1 includes the wiring layer 22, the wiring layer WA, and the wiring layer WB. The wiring layer 22 is arranged in the layer M0 as the lowermost layer of the plurality of layers M0 to M4, R0, and R1, the wiring layer WA is arranged in the layer R1 as the uppermost layer and thicker than the wiring layer 22, and the wiring layer WB is arranged in the layer R1 as the uppermost layer, thicker than the wiring layer WA, and has a thickness 40 times or more the thickness of the wiring layer 22.

In this way, the wiring layers WA and WB having different thicknesses are allowed to be formed at the final stage of the back-end-of-line process.

In addition, for example, the thickness of the wiring layer WB 40 times or more the thickness of the wiring layer 22 makes it possible to reduce on-resistance to improve output from each transistor TR when the wiring layer WB functions as the electrode pad connected to the bonding wire. In addition, the heat dissipation characteristic of the wiring layer WB can be improved to improve breakdown resistance, and the occurrence of damage in the lower layers M0 to M4 and the like due to a load upon bonding with the bonding wire can be suppressed.

Meanwhile, for example, forming the wiring layer WA functioning as the re-distribution layer or the like into the thin layer makes it possible to apply a finer design rule to the wiring layer WA, without increasing the number of layers of the semiconductor device 1. Therefore, it is possible to facilitate reduction in the process cost and reduction of the size of the semiconductor device 1.

As described above, it is possible to satisfy different requirements for improvement of device characteristic by forming the thick film and reduction of the design rules.

According to the semiconductor device 1 of the first embodiment, the wiring layer WB has the upper surface exposed from the opening portion 50p of the insulating layer 50. This configuration makes it possible to make the wiring layer WB function as the electrode pad.

According to the semiconductor device 1 of the first embodiment, the wiring layer WA includes the plating layer 52 that includes a metal such as Cu, and the barrier metal layer 51 that includes a metal different from the metal of the plating layer 52 and that is arranged below the plating layer 52, and on the plating layer 52 of the wiring layer WB, the coating layer 53 is selectively arranged that includes a metal such as Ti or TiW different from the metal of the plating layer 52 and that is arranged on the upper side of the plating layer 52.

As described above, the coating layer 53 is formed only in the wiring layer WB and the wiring layer WA eliminates the need for the coating layer 53, and therefore, the process cost can be further reduced.

### Second Embodiment

Hereinafter, a second embodiment will be described in detail with reference to the drawings. A semiconductor device according to the second embodiment is different from the semiconductor device according to the first embodiment described above in that some of wiring layers are formed without making contact with a layer therebelow.

In the following drawings, the same reference numerals are given to the same configurations as those of the first embodiment described above, and the descriptions thereof may be omitted.

### (Exemplary Configuration of Semiconductor Device)

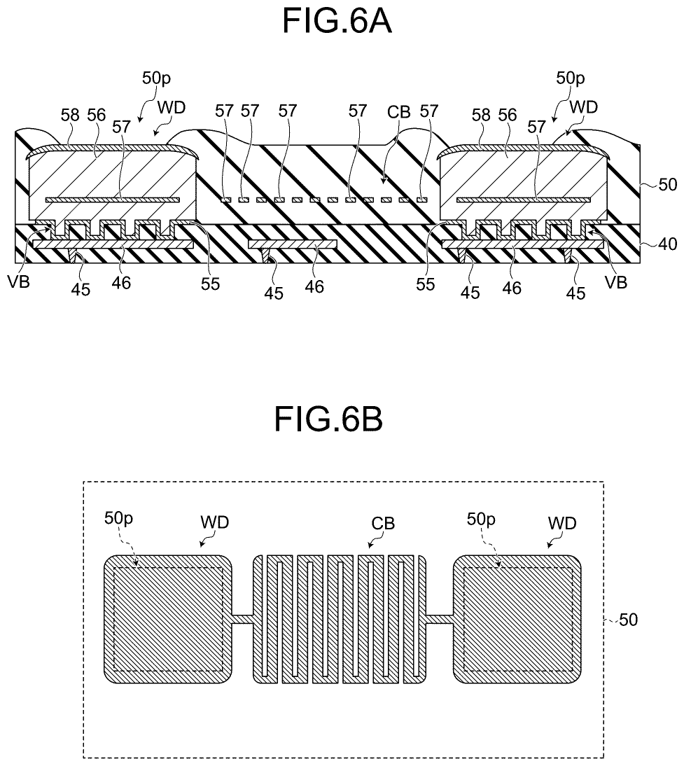

FIGS. 6A and 6B are diagrams each illustrating an exemplary configuration of a semiconductor device according to a second embodiment. More specifically, FIG. 6A is a cross-sectional view of a partial configuration including a layer as an uppermost layer of the semiconductor device of the second embodiment, and FIG. 6B is a top view of the layer as the uppermost layer of the semiconductor device of the second embodiment. However, FIG. 6B illustrates a configuration covered with the insulating layer 50 as viewed through the insulating layer 50.

As illustrated in FIGS. 6A and 6B, also in the semiconductor device of the second embodiment, the insulating layer 50 is arranged in the layer as the uppermost layer, and the insulating layer 40 is arranged in a layer below the layer as the uppermost layer. In the insulating layer 40, a via 45 and a wiring layer 46 belonging to a layer below the layer as the uppermost layer are arranged.

In addition, a plurality of vias VB connected to the wiring layer 46 are arranged in the insulating layer 40, and these vias VB are connected to a wiring layer WD arranged in the insulating layer 50 belonging to the layer as the uppermost layer. The wiring layer CB is also disposed in the insulating layer 50.

The wiring layer CB as the second metal layer has, for example, a meandering shape in which a thin line meanders several times as viewed from above, and is arranged above the insulating layer 40 without making contact with the insulating layer 40 therebelow. Therefore, the wiring layer CB is arranged, for example, inside the insulating layer 50 while being separated from the insulating layer 40. However, the wiring layer CB may have a comb shape or a membrane shape. In either configuration, the wiring layer CB is configured to exclusively include an intermediate layer 57.

The wiring layer WD as the third metal layer, has, for example, a pad shape as viewed from above, and has an upper surface partially exposed from the opening portion 50p of the insulating layer 50. The wiring layer WD also has a thickness 40 times, more preferably 40 times or more and 80 times or less the thickness of the wiring layer in the layer as the lowermost layer.

In addition, the wiring layer WD has a configuration in which a barrier metal layer 55 as the second layer, a plating layer 56 as the first layer, and a coating layer 58 are stacked in this order. The wiring layer WD includes the intermediate layer 57 as the third layer interposed in the plating layer 56, and a seed layer, which is not illustrated, interposed between the barrier metal layer 55 and the plating layer 56.

The barrier metal layer 55 is, for example, a Ti layer or TiW layer, similarly to the barrier metal layer 51 described above. The seed layer, which is not illustrated, and the plating layer 56 are each, for example, a Cu layer or the like, similarly to the seed layer and the plating layer 52 which are described above. In this configuration, Cu is an example of the first metal. The intermediate layer 57 is, for example, a Si layer, Pd layer, or the like. In this configuration, Si or Pd is an example of the second metal. Similarly to the coating layer 53 described above, the coating layer 58 is, for example, a NiPd layer, NiAu layer, NiPdAu layer, Au layer, or the like.

The intermediate layer 57 of the wiring layer WD is connected to the intermediate layer 57 of the wiring layer CB, and whereby the wiring layer WD functions as an anchor to support the wiring layer CB arranged above the insulating layer 40. The wiring layer WD may also have a function as the electrode pad.

The wiring layer WD is arranged on one or both sides of the wiring layer CB described above to support the wiring layer CB, and the wiring layer CB has a cantilever beam structure or a fixed beam structure.

Meanwhile, the wiring layer CB as a thin layer functions as, for example, an inductor. Alternatively, the wiring layer CB as a thin layer may function as a sensor or the like to sense pressure, a gas, a sound wave, or the like in the atmosphere around the semiconductor device of the second embodiment, or may function as a movable spring, a micromirror, or the like. In this configuration, instead of burying the wiring layer CB in the insulating layer 50, a gap serving as a movable range for the wiring layer CB may be provided therearound.

As described above, the portion of the layer as the uppermost layer of the semiconductor device of the second embodiment is allowed to be configured as, for example, the inductor or a micro electro mechanical system (MEMS).

Furthermore, in the portions of layers below the uppermost layer, the semiconductor device of the second embodiment can include a transistor, a contact connected to the transistor, a via, a wiring layer, and the like, similarly to the semiconductor device 1 of the embodiment described above. Such portions of the lower layers of the semiconductor device are configured as, for example, a control circuit or the like to control the inductor or MEMS in the portion of the uppermost layer.

### (Method of Manufacturing Semiconductor Device)

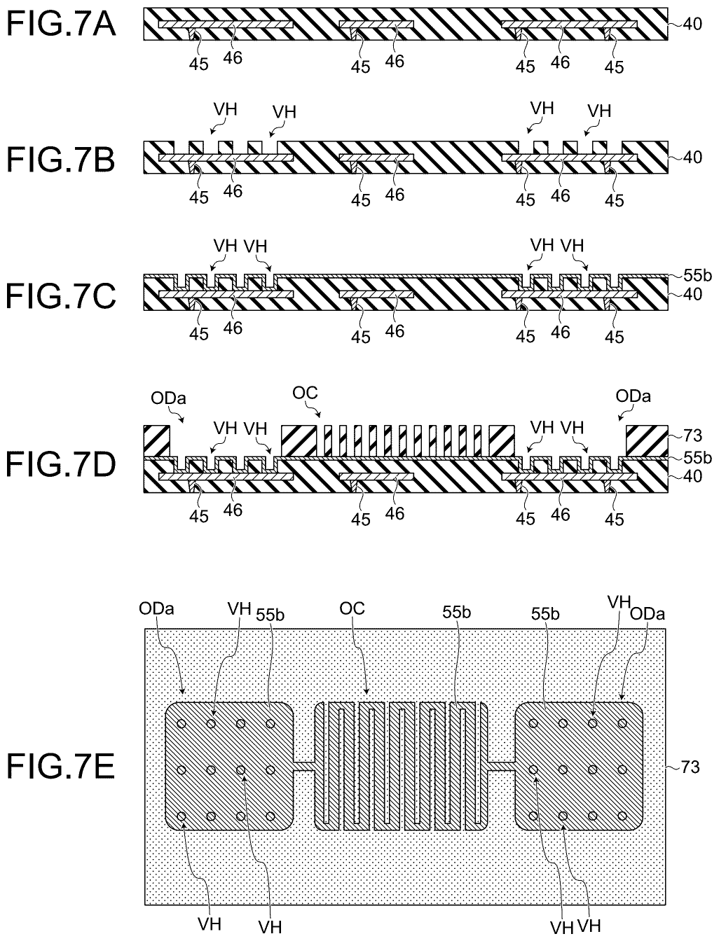

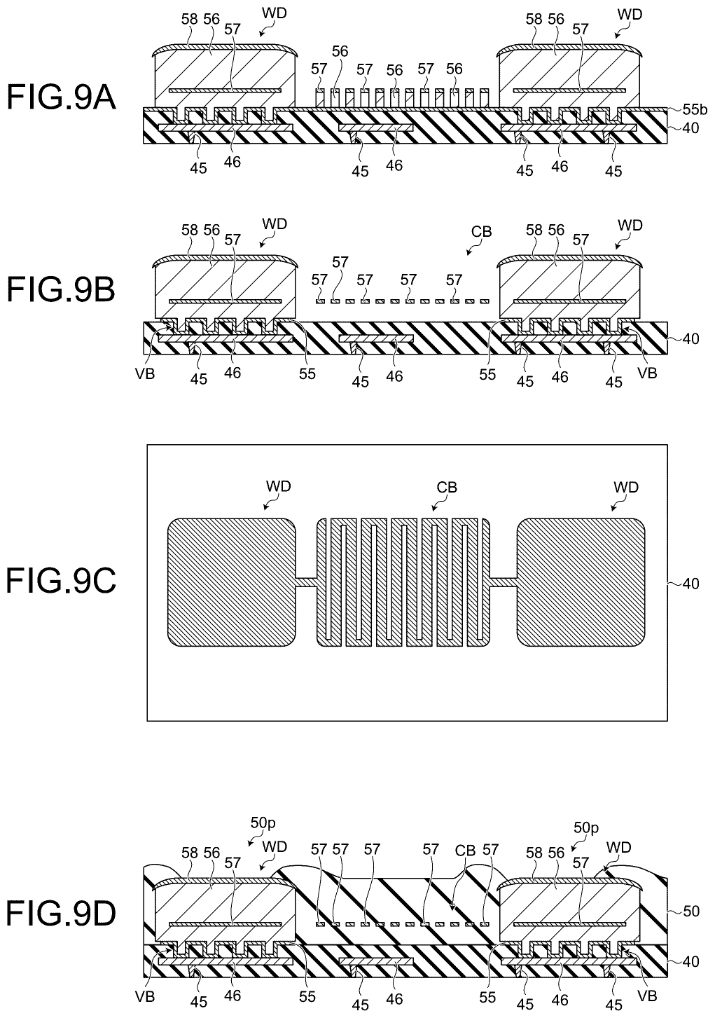

Next, a method of manufacturing the semiconductor device according to the second embodiment will be described with reference to FIGS. 7A to 9D. FIGS. 7A to 9D are diagrams illustrating an example of a procedure of the method of manufacturing the semiconductor device according to the second embodiment. FIGS. 7E and 9C of FIGS. 7A to 9D are top views of the semiconductor device in progress, and others are cross-sectional views of the semiconductor device in progress.

Note that FIGS. 7A to 9D mainly illustrate a method of forming various configurations, in the layer as the uppermost layer of the semiconductor device of the second embodiment.

As illustrated in FIG. 7A, the vias 45 and the wiring layers 46 have been formed in the insulating layer 40.

As illustrated in FIG. 7B, the insulating layer 40 is processed to form the plurality of via holes VH reaching the wiring layers 46.

As illustrated in FIG. 7C, a barrier metal layer 55b and the seed layer are formed on the surface of the insulating layer 40 and the side surface and bottom surface of each of the via holes VH by, for example, sputtering or the like. The barrier metal layer 55b and the seed layer are preferably formed continuously.

As illustrated in FIG. 7D, a mask pattern 73 as the first mask pattern such as a photoresist layer is formed to cover the insulating layer 40, the barrier metal layer 55b on the insulating layer 40, and the like. The mask pattern 73 has an opening portion ODa as a second opening portion, at a position where the via holes VH are formed, and has an opening portion OC as the first opening portion at a position away from the opening portion ODa.

As illustrated in FIG. 7E, the opening portion OC of the mask pattern 73 has, for example, a meandering shape in which an opening portion of a narrow trench meanders several times and is partially connected to the opening portion ODa.

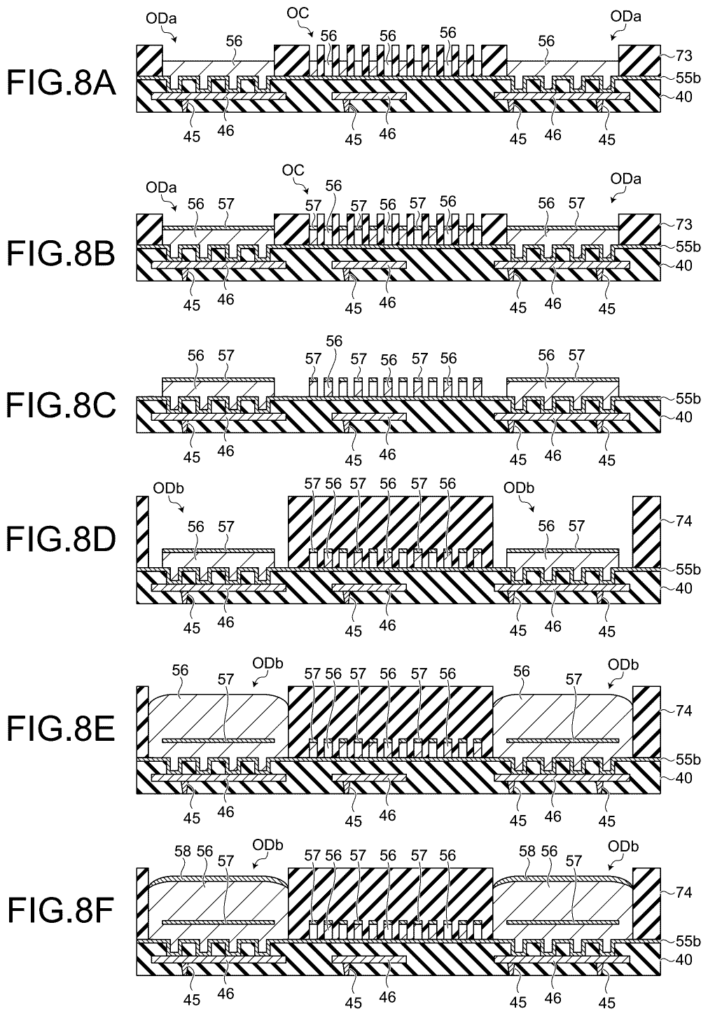

As illustrated in FIG. 8A, the plating layer 56 of a metal as the first metal such as Cu is formed by electrolytic plating or the like, using as an electrode, the seed layer on the barrier metal layer 55b exposed from the opening portions OC and ODa of the mask pattern 73. The plating layer 56 as the first metal layer is formed to be thicker than at least the wiring layer in the layer as the lowermost layer, and further, thicker than each of the wiring layers 46 formed in the insulating layer 40 therebelow.

As illustrated in FIG. 8B, the intermediate layer 57 as the second layer such as a Si layer or Pd layer is formed on the plating layer 56 in the opening portions OC and ODa of the mask pattern 73. The Si layer can be formed by, for example, CVD or the like, and the Pd layer can be formed by, for example, electroless plating or the like. The metal such as Si or Pd constituting the intermediate layer 57 is an example of the second metal, and has wet etching resistance higher than, for example, that of the metal constituting the barrier metal layer 55b, the plating layer 56, and the like.

As illustrated in FIG. 8C, the mask pattern 73 is removed by ashing or the like using oxygen plasma.

As illustrated in FIG. 8D, a mask pattern 74 as the second mask pattern such as a photoresist layer is formed to cover the insulating layer 40, the barrier metal layer 55b on the insulating layer 40, and part of the plating layer 56 and the intermediate layer 57. The mask pattern 74 has an opening portion ODb as the third opening portion larger than, for example, the opening portion ODa at a position overlapping with the opening portion ODa of the mask pattern 73 described above.

As illustrated in FIG. 8E, a metal as a third metal such as Cu is formed to be further thicker by electrolytic plating or the like, by using the intermediate layer 57 exposed from the opening portion ODb of the mask pattern 74 as an electrode. Therefore, on the basis of the plating layer 56 and the intermediate layer 57 having been already formed into a small-size, the plating layer 56 is formed into a thick film, having a shape in which the upper surface is rounded, having a thickness that is 40 times or more the thickness of the wiring layer in the layer as the lowermost layer.

As illustrated in FIG. 8F, the coating layer 58, such as a NiPd layer, NiAu layer, NiPdAu layer, or Au layer, is formed on the plating layer 56 formed into the thick film, which is formed in the opening portion ODb of the mask pattern 74 by, for example, electroless plating or the like.

As illustrated in FIG. 9A, the mask pattern 74 is removed by ashing or the like using oxygen plasma.

As illustrated in FIG. 9B, the barrier metal layer 55b and the seed layer are removed from the surface of the insulating layer 40 located at portions not covered with the intermediate layer 57, the coating layer 58, or the like, by wet etching or the like.

Therefore, in portions covered with the coating layer 58, the barrier metal layer 55 and the seed layer that have a pattern of the wiring layer WD are formed with respect to the plating layer 56 thereabove to have a side etched shape, and the plating layer 56 itself is also partially etched to form the wiring layer WD recessed in the width direction.

On the other hand, in a portion covered with the intermediate layer 57, the intermediate layer 57 and the plating layer 56 have a thin line shape, and therefore, the barrier metal layer 55 and the seed layer disappear together with the plating layer 56 thereabove. At this time, the intermediate layer 57 including the metal having the wet etching resistance higher than that of the metal of the seed layer, the plating layer 56, and the like remains without being removed. Therefore, the wiring layer CB having the intermediate layer 57 separated upward from the insulating layer 40 and supported by the wiring layer WD is formed. This state is illustrated in the top view of FIG. 9C.

As illustrated in FIG. 9D, the opening portion 50p is provided at a position where the wiring layer WD is formed, and the insulating layer 50 such as the polyimide layer covering the insulating layer 40 including the wiring layer CB is formed.

As described above, the semiconductor device according to the second embodiment is manufactured.

### (Overview)

According to the semiconductor device of the second embodiment, the wiring layer CB is arranged above a layer therebelow without making contact with the layer therebelow. The wiring layer CB configured in this way makes it possible to constitute the semiconductor device including the inductor, MEMS, or the like at low cost.

According to the semiconductor device of the second embodiment, the wiring layer CB includes a metal such as Si or Pd different from the metal of the plating layer 56, and the wiring layer WD includes the intermediate layer 57 including the metal different from the metal of the plating layer 56, at a height position equal to that of the wiring layer CB in the plating layer 56. Each layer of the wiring layers WD and CB constituted in this way makes it possible to constitute the wiring layer CB so as to be arranged above a layer therebelow without making contact with the layer therebelow.

According to the semiconductor device of the second embodiment, the wiring layer WD is connected to the wiring layer CB to serve as the anchor to support the wiring layer CB, and the wiring layer CB has the cantilever beam structure or fixed beam structure having a comb shape, a meandering shape, or a membrane shape. This configuration makes it possible to make the wiring layer CB function as the inductor, sensor, or the like.

The semiconductor device according to the second embodiment provides effects similar to those of the semiconductor device 1 according to the first embodiment described above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a transistor; and
a plurality of metal layers that is respectively arranged in a plurality of layers stacked above the transistor, wherein
the plurality of metal layers includes:
a first metal layer that is arranged in a lowermost layer of the plurality of layers;
a second metal layer that is arranged in an uppermost layer of the plurality of layers and that is thicker than the first metal layer; and
a third metal layer that is arranged in the uppermost layer and that is thicker than the second metal layer.

2. The semiconductor device according to claim 1, wherein
the third metal layer has a thickness 40 times or more a thickness of the first metal layer.

3. The semiconductor device according to claim 1, wherein
the third metal layer has a round shape with an outer edge portion rounded.

4. The semiconductor device according to claim 1, further comprising
an insulating layer that is arranged in the uppermost layer and has an opening portion, wherein
the second metal layer is covered with the insulating layer, and
the third metal layer has an upper surface exposed from the opening portion.

5. The semiconductor device according to claim 4, wherein
the third metal layer includes:
a first layer that includes a first metal;
a second layer that includes a metal different from the first metal and is arranged below the first layer; and
a third layer that includes a second metal different from the first metal and is arranged above the first layer.

6. The semiconductor device according to claim 5, wherein
the second metal layer includes:
the first layer; and
the second layer, and
the third layer is selectively arranged on the first layer of the third metal layer of the second and third metal layers.

7. The semiconductor device according to claim 4, wherein
at least part of a metal layer arranged in a layer below the uppermost layer of the plurality of metal layers is electrically connected to the transistor,
the second metal layer is a re-distribution layer that changes a wiring drawn position of the at least part of the metal layer, and
the third metal layer is an electrode pad that is connectable to an external device.

8. The semiconductor device according to claim 1, wherein
the third metal layer is arranged on a layer below the uppermost layer, and
the second metal layer is arranged above the layer below without making contact with the layer below.

9. The semiconductor device according to claim 8, wherein
the third metal layer includes:
a first layer that includes a first metal; and
a second layer that includes a metal different from the first metal and is arranged below the first layer.

10. The semiconductor device according to claim 9, wherein
the second metal layer includes a second metal that is different from the first metal, and
the third metal layer further includes a third layer that includes the second metal at a height position equal to that of the second metal layer, in the first layer.

11. The semiconductor device according to claim 8, wherein
the third metal layer is connected to the second metal layer and serves as an anchor to support the second metal layer, and
the second metal layer has a cantilever beam structure or fixed beam structure having a comb shape, a meandering shape, or a membrane shape.

12. The semiconductor device according to claim 11, wherein
the third metal layer is an electrode pad that is connectable to an external device.

13. A method of manufacturing a semiconductor device comprising:
forming a transistor on a substrate;
stacking a plurality of layers each including a plurality of metal layers above the transistor;
when forming a lowermost layer of the plurality of layers,
forming a first metal layer that is part of the plurality of metal layers and is electrically connected to the transistor;
when forming an uppermost layer of the plurality of layers,
forming a first mask pattern that has first and second opening portions, on a layer below the uppermost layer;
forming a second metal layer in each of the first and second opening portions by electrolytic plating, the second metal layer being part of the plurality of metal layers and thicker than the first metal layer;
forming a second mask pattern that has a third opening portion at a position overlapping with the first opening portion, on the layer below; and
further performing electrolytic plating on the second metal layer exposed from the third opening portion to form a third metal layer in the third opening portion, the third metal layer being part of the plurality of metal layers and obtained by increasing a thickness of the second metal layer.

14. The method of manufacturing a semiconductor device according to claim 13, wherein
the third metal layer has a thickness 40 times or more a thickness of the first metal layer.

15. The method of manufacturing a semiconductor device according to claim 13, wherein
when forming the second metal layer, forming a first layer including a first metal in the first and second opening portions by the electrolytic plating.

16. The method of manufacturing a semiconductor device according to claim 15, wherein
when forming the third metal layer, forming a second layer including a second metal different from the first metal, on the first layer.

17. The method of manufacturing a semiconductor device according to claim 16, further comprising
forming an insulating layer on the layer below, the insulating layer covering the second metal layer and having an opening portion from which an upper surface of the third metal layer is exposed.

18. The method of manufacturing a semiconductor device according to claim 17, wherein
when forming the plurality of metal layers,
electrically connecting at least part of a metal layer arranged in the layer below, of the plurality of metal layers, to the transistor;
when forming the first mask pattern,
forming the second opening portion at a position to which the second metal layer changes a wiring drawn position of the at least part of the metal layer; and
forming the second opening portion at a position where the third metal layer is connectable to an external device.

19. The method of manufacturing a semiconductor device according to claim 15, wherein
when forming the second metal layer,
forming a second layer including a second metal different from the first metal, on the first layer; and
removing the first layer in the second metal layer formed in the second opening portion after the third metal layer is formed, and arranging the second layer for the second metal layer above the layer below without bringing the second layer into contact with the layer below.

20. The method of manufacturing a semiconductor device according to claim 19, wherein
when forming the third metal layer, partially connecting the third metal layer to the second metal layer formed in the second opening portion; and
when removing the first layer, forming the second layer having a cantilever beam structure or fixed beam structure having a comb shape, meandering shape, or a membrane shape.
